(19) United States
(12) Patent Application Publication
(10) Pub. No.: US 2012/0056313 A1
(43) Pub. Date: Mar. 8, 2012

(54) SEMICONDUCTOR PACKAGE

(76) Inventors: Masashi AIZAWA, Yokohama-shi (JP); Jun Morimoto, Yokohama-shi (JP); Masayuki Kato, Kawasaki-shi (JP)

(21) Appl. No.: 13/224,631

(22) Filed: Sep. 2, 2011

(30) Foreign Application Priority Data
Sep. 3, 2010 (JP) 2010-198056

(51) Int. Cl. H01L 23/40

(52) U.S. Cl. 257/691; 257/E23.083

(57) ABSTRACT

A semiconductor package includes a radiator plate including a stress alleviation section, a resin sheet arranged on the radiator plate, a pair of bus bars joined to the radiator plate through the resin sheet at positions at which the stress alleviation section is interposed between the bus bars, and a semiconductor device joined to the pair of bus bars by being sandwiched between the bus bars, and energized from outside through the pair of bus bars.

### CROSS-REFERENCE TO RELATED APPLICATIONS

This application is based upon and claims the benefit of priority from prior Japanese Patent Application No. 2010-198056, filed Sep. 3, 2010, the entire contents of which are incorporated herein by reference.

### FIELD

This embodiment relates to a semiconductor package or the like used for a power semiconductor device to be used in a vehicle-mounted inverter.

### BACKGROUND

In, for example, an electric vehicle, size reduction, acquisition of high reliability, and improvement in cooling efficiency of a power semiconductor device and inverter unit in which the power semiconductor device is used are required. Thus, a structure of a semiconductor device such as an insulated gate bipolar transistor (IGBT) or the like in which cooling efficiency is increased is known.

A semiconductor package which can prevent a crack from occurring in a resin sheet even when deformation of the resin sheet is repeated concomitantly with the temperature rise/fall of the semiconductor device, and extend the product life is desired.

### BRIEF DESCRIPTION OF THE DRAWINGS

FIG. 1 is a perspective view showing a semiconductor package according to a first embodiment.

FIG. 2 is a side view schematically showing an important part of the semiconductor package.

FIG. 3 is a side view schematically showing an important part of a semiconductor package according to a second embodiment.

FIG. 4 is a side view schematically showing an important part of a semiconductor package according to a third embodiment.

FIG. 5 is a plan view schematically showing an important part of a semiconductor package according to a fourth embodiment.

FIG. 6 is a plan view schematically showing an important part of a semiconductor package according to a fifth embodiment.

### DETAILED DESCRIPTION

A semiconductor package according to an embodiment is provided with a radiator plate including a stress alleviation section, resin sheet arranged on the radiator plate, a pair of bus bars joined to the radiator plate through the resin sheet at positions at which the stress alleviation section is interposed between the bus bars, and semiconductor device joined to the pair of bus bars by being sandwiched between the bus bars, and energized from outside through the pair of bus bars.

A semiconductor package according to an embodiment is provided with a radiator plate, resin sheet arranged on the radiator plate, a pair of bus bars joined to the radiator plate through the resin sheet, and provided with a stress diversification section on a surface on which the bus bars are in contact with the resin sheet, and semiconductor device joined to the pair of bus bars by being sandwiched between the bus bars, and energized from outside through the pair of bus bars.

### First Embodiment

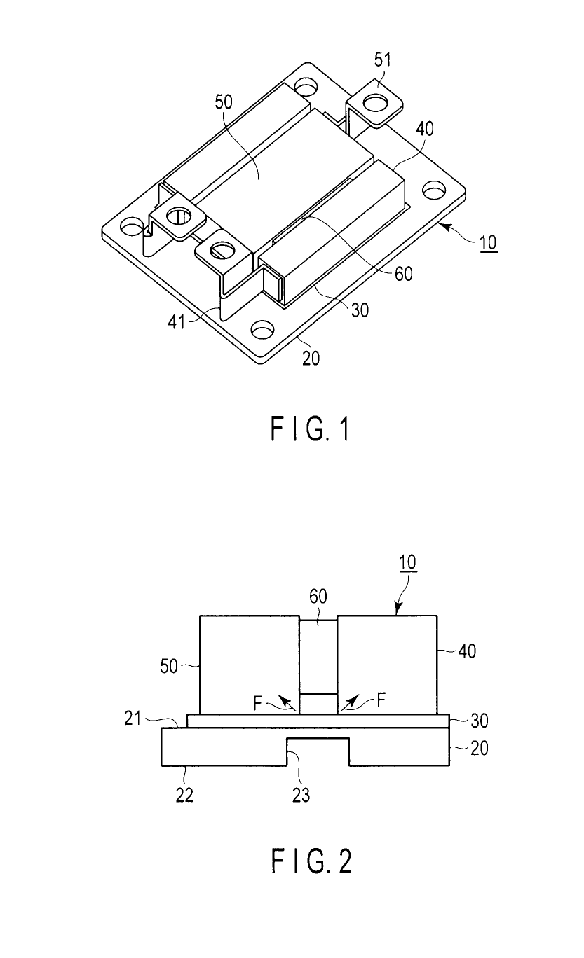

FIG. 1 is a perspective view showing a semiconductor package 10 according to a first embodiment, and FIG. 2 is a side view schematically showing an important part of the semiconductor package 10.

The semiconductor package 10 is provided with a radiator plate 20 connected to a cooling tube or the like, a pair of bus bars 40 and 50 joined to the surface 21 of the radiator plate 20 through an epoxy sheet (resin sheet) 30, and semiconductor device 60 such as an IGBT or the like sandwiched between the pair of bus bars 40 and 50.

The radiator plate 20 is provided with a rectangular groove section (stress alleviation section) 23 on the back surface 22 side thereof. The groove section 23 is provided at an intermediate position of the bus bars 40 and 50, and is arranged in opposition to the semiconductor device 60. The bus bars 40 and 50 are provided with terminals 41 and 51 through which power is supplied from outside. That is, power is supplied to the semiconductor device 60 through the bus bars 40 and 50.

The radiator plate 20 is formed of a copper/aluminum material, has high thermal conductivity, and is flexible. Further, the epoxy sheet 30 is a resin sheet having pressure resistance, insulation properties, and thermal conductivity, and is formed of, for example, a sheet of an insulating resin filled with a ceramic filler such as boron nitride or the like. In this case, the thermal conductivity is 2 to 4 W/mK, and thickness is about 0.05 to 0.15 mm. Furthermore, the bus bars 40 and 50 are made of a copper material, and have high thermal conductivity and electrical conductivity.

The semiconductor package 10 is manufactured by the following processes. That is, the semiconductor device 60 and bus bars 40 and 50 are joined to each other by using a low-melting-point solder of an Sn—Pb alloy or the like, or high-melting-point solder of an Sn—Ag—Cu alloy or the like. It should be noted that they may be joined by using an electrically conductive adhesive such as a silver paste or the like.

Subsequently, the bus bars 40 and 50, and radiator plate 20 are joined to each other by thermo-compressive bonding with the epoxy sheet interposed between the bus bars 40 and 50, and radiator plate 20. Thereafter, the radiator plate 20 and cooling tube are joined to each other, further a lead is connected to each of the terminals 41 and 51, and then the terminals 41 and 51 are attached to the bus bars 40 and 50.

The semiconductor package configured as described above operates in the following manner. That is, the semiconductor device 60 is energized through the bus bars 40 and 50 in order to operate the inverter. The semiconductor device 60 is supplied with power, whereby the semiconductor device 60 generates heat. At this time, force is applied to the semiconductor package 10 in the directions F indicated by arrows in FIG. 2 because of differences in the coefficients of thermal expansion of the semiconductor device 60, bus bars 40 and 50, and radiator plate 20, whereby the semiconductor package 10 is deformed.

On the other hand, the radiator plate 20 is provided with the groove section 23, and hence is easily deformed, and epoxy sheet 30 is also deformed following the bus bars 40 and 50. Thereby, the stresses to be applied to the epoxy sheet 30 are alleviated, and a crack can be prevented from occurring in the epoxy sheet 30. It should be noted that the groove section 23 is not positioned at a point on the pathway of heat transmission from each of the bus bars 40 and 50 to the radiator plate 20, and hence the groove section 23 does not adversely affect the heat radiation efficiency.

As described above, according to the semiconductor package 10 associated with this embodiment, even when deformation of the epoxy sheet 30 is repeated concomitantly with the temperature rise/fall of the semiconductor device 20, it is possible to prevent a crack from occurring in the epoxy sheet 30, and extend the product life.

### Second Embodiment

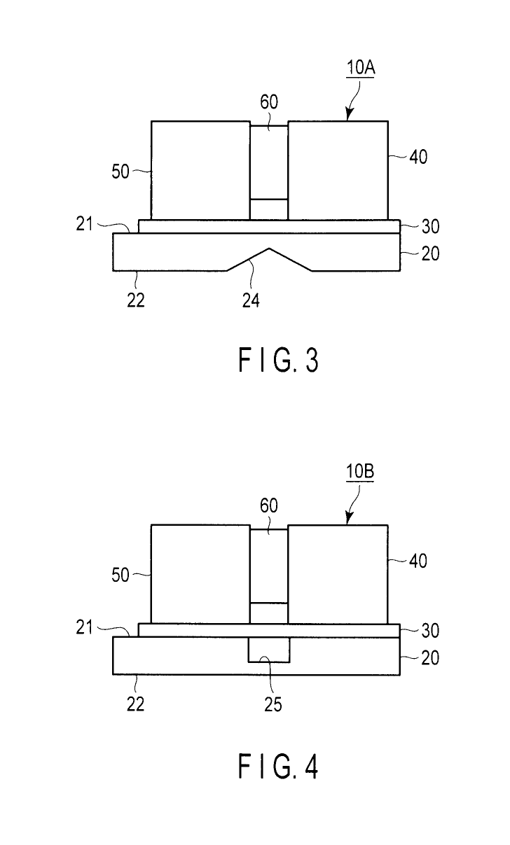

FIG. 3 is a side view schematically showing an important part of a semiconductor package 10A according to a second embodiment. It should be noted that in FIG. 3, functional parts identical to those in FIG. 2 are denoted by the identical reference symbols, and a detailed description of them will be omitted.

In the semiconductor package 10A, in place of the rectangular groove section 23, a tapered groove section (stress alleviation section) 24 is provided. Even in this case, it is possible to obtain an advantage identical to the semiconductor package 10.

### Third Embodiment

FIG. 4 is a side view schematically showing an important part of a semiconductor package 10B according to a third embodiment. It should be noted that in FIG. 4, functional parts identical to those in FIG. 2 are denoted by the identical reference symbols, and a detailed description of them will be omitted.

In the semiconductor package 10B, a rectangular groove section (stress alleviation section) 25 is provided not on the back surface 22 side of the radiator plate 20, but on the top surface 21 side thereof. Even in this case, it is possible to obtain an advantage identical to the semiconductor package 10.

### Fourth Embodiment

FIG. 5 is a plan view schematically showing an important part of a semiconductor package 10C according to a fourth embodiment. It should be noted that in FIG. 5, functional parts identical to those in FIG. 2 are denoted by the identical reference symbols, and a detailed description of them will be omitted.

In the semiconductor package 10C, C-chamfered sections 42 and 52 of the bus bars 40 and 50 are formed. When the C-chamfered sections 42 and 52 are formed as described above, the maximum stresses occurring at the corner parts of the bus bars 40 and 50 are diversified, and stresses applied to the epoxy sheet 30 are reduced. By virtue of the reduction in stresses, the number of times of occurrence of deformation to be applied to the epoxy sheet 30 until a crack is caused in the epoxy sheet 30 by fatigue failure is increased, and product life can be extended. Accordingly, an advantage identical to the semiconductor package 10 can be obtained.

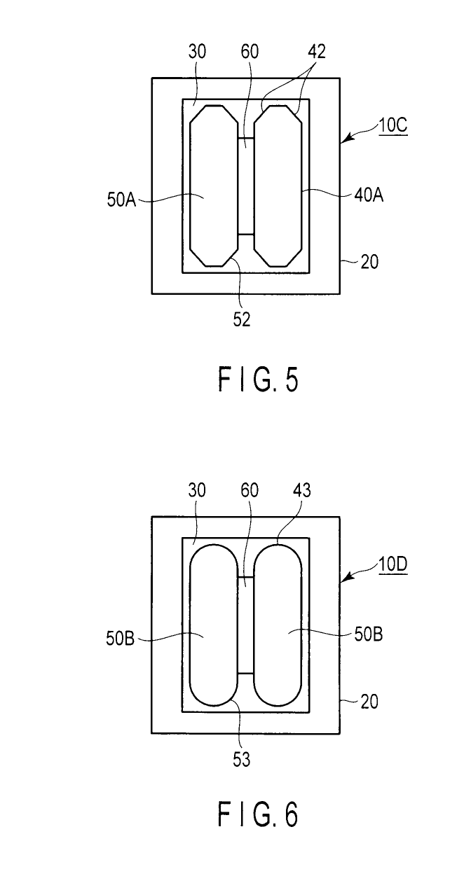

FIG. 6 is a plan view schematically showing an important part of a semiconductor package 10D according to a fifth embodiment. It should be noted that in FIG. 6, functional parts identical to those in FIG. 2 are denoted by the identical reference symbols, and a detailed description of them will be omitted.

In the semiconductor package 10D, R-shaped sections 43 and 53 are provided in place of the C-chamfered sections. In this case too, the stresses are diversified, and hence an advantage identical to the semiconductor package 10C can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor package comprising:
a radiator plate including a stress alleviation section;
a resin sheet arranged on the radiator plate;
a pair of bus bars joined to the radiator plate through the resin sheet at positions at which the stress alleviation section is interposed between the bus bars; and
a semiconductor device joined to the pair of bus bars by being sandwiched between the bus bars, and energized from outside through the pair of bus bars.

2. The semiconductor package according to claim 1, wherein
the stress alleviation section is a rectangular groove section provided on the opposite side of the radiator plate to the semiconductor device.

3. The semiconductor package according to claim 1, wherein
the stress alleviation section is a groove section provided on the semiconductor device side of the radiator plate.

4. The semiconductor package according to claim 1, wherein
the stress alleviation section is a tapered groove section provided on the opposite side of the radiator plate to the semiconductor device.

5. A semiconductor package comprising:
a radiator plate;
a resin sheet arranged on the radiator plate;
a pair of bus bars joined to the radiator plate through the resin sheet, and provided with stress diversification sections on a surface on which the bus bars are in contact with the resin sheet; and
a semiconductor device joined to the pair of bus bars by being sandwiched between the bus bars, and energized from outside through the pair of bus bars.

6. The semiconductor package according to claim 5, wherein
the stress diversification sections are chamfered sections provided on the pair of bus bars.

7. The semiconductor package according to claim 5, wherein
the stress diversification sections are R-shaped sections provided on the pair of bus bars.
